(19) United States
(12) Patent Application Publication
(10) Pub. No.: US 2008/0011230 A1
(43) Pub. Date: Jan. 17, 2008

(54) CHEMICAL VAPOR DEPOSITION EQUIPMENT

(76) Inventors: Chih-Wei Ke, Tao-Yuan Hsien (TW); Jen-Chi Chuang, Tao-Yuan Hsien (TW); Shih-Heng Fan, Tao-Yuan Hsien (TW)

Correspondence Address: NORTH AMERICA INTELLECTUAL PROPERTY CORPORATION, P.O. BOX 506, MERRIFIELD, VA, 22116, US

(21) Appl. No.: 11/382,714

(22) Filed: May 11, 2006

(30) Foreign Application Priority Data
Nov. 21, 2005 (TW) 094140788

(51) Int. Cl. C23C 16/00

(52) U.S. Cl. 118/715

(57) ABSTRACT

Chemical vapor deposition equipment includes a reactor, an adjustable pipe, and an exhausted pipe. The adjustable pipe includes a compressible body, a bushing, and a ring positioned at an end of the body for connecting with the exhausted pipe. The bushing is positioned inside the body, and an end of the bushing is connected to the reactor for preventing exhaust gas from remaining inside the body. In addition, the compressible body is monolithically formed. Therefore, exhaust gas will not leak from the body, which improves the quality of manufacture.

### BACKGROUND OF THE INVENTION

1. Field of the Invention

The present invention relates to chemical vapor deposition equipment, and more particularly, to chemical vapor deposition equipment having an adjustable pipe to connect an exhausted pipe and an exhaust end of a reactor.

2. Description of the Prior Art

Chemical vapor deposition (CVD) is a chemical process that transforms a reactant (usually a gas) into a solid product in a reactor. It is a common thin-film deposition technique that deposits the product onto the surface of a wafer. Plasma-enhanced chemical vapor deposition (PECVD) ionizes the gas reactant with plasma so as to decrease reaction temperature. In both CVD and PECVD exhaust gas is generated inside the reactor and should be released to improve manufactured product quality.

Please refer to FIG. 1, which is a diagram of reactors 10 connected to exhausted pipes 12. Each reactor 10 includes two exhaust ends connected to the exhausted pipes 12 for releasing exhaust gas. Therefore, a leak-proof expansion pipe 40 is used for engaging the exhaust end of the reactor 10 and the exhausted pipe 12. Both ends of the leak-proof expansion pipe 40 must fit the exhaust end of the reactor 10 and the exhausted pipe 12, so that exhaust gas pumped by a pump does not leak to contaminate the equipment. In addition, the leak-proof expansion pipe 40 is made of aluminum alloy so that contaminants are prevented from remaining inside the leak-proof expansion pipe 40 when releasing exhaust gas.

Please refer to FIG. 2, which is a diagram of the leak-proof expansion pipe 40 according to the prior art. The leak-proof expansion pipe 40 comprises sleeves 20 and 30. Please refer to FIG. 3 and FIG. 4, which respectively show the two sleeves 20 and 30 of which the leak-proof expansion pipe 40 is made based on the prior art. The sleeve 20 of FIG. 3 includes a plurality of penetrating holes 24. The sleeve 20 is hollow (indicated by numeral 22), and there is a recess 26 inside the sleeve 20 for accommodating a perfluor O-ring. The sleeve 30 of FIG. 4 is also hollow and includes a plurality of screw holes 34. The sleeve 30 can be inserted into the hollow part 22 of the sleeve 20 of FIG. 3. The two sleeves 20 and 30 are firmly connected by bolts 44 and springs 42, as shown in FIG. 2.

As mentioned above, the leak-proof expansion pipe 40 is composed of two sleeves 20 and 30. However, when the two sleeves 20 and 30 are connected, the long portion 32 does not contact the hollow part 22 closely. In order to prevent exhaust gas from leaking from the connection portion between the long portion 32 and the hollow part 22, the prior art places a perfluor O-ring inside the recess 26 to seal the connection portion to be somewhat leak proof. However, the O-ring can easily be deteriorated by the temperature of the reactor 10 and gas, and thereby exhaust gas can leak from the connection portion to contaminate the equipment and the environment.

### SUMMARY OF THE INVENTION

The claimed invention discloses chemical vapor deposition equipment. The chemical vapor deposition equipment comprises a reactor, an adjustable pipe, and an exhausted pipe. The reactor comprises an exhaust end. The adjustable pipe comprises a compressible body, a bushing, and a ring. The compressible body includes a bellows. The bushing is positioned inside the bellows and an end of the bushing is connected to the exhaust end of the reactor. The ring is positioned at an end of the compressible body. The exhausted pipe is connected to the ring of the adjustable pipe for releasing exhaust gas.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of reactors connected to exhausted pipes according to the prior art.

FIG. 2 is a diagram of a leak-proof expansion pipe according to the prior art.

FIG. 3 and FIG. 4 respectively show two sleeves of which the leak-proof expansion pipe of FIG. 2 is made based on the prior art.

FIG. 5 is a diagram of chemical vapor deposition equipment according to the present invention.

FIG. 6 is a structure of an adjustable pipe according to the present invention.

FIG. 7 is a structure of a bushing of the adjustable pipe according to the present invention.

FIG. 8 is a structure of a compressible body of the adjustable pipe according to the present invention.

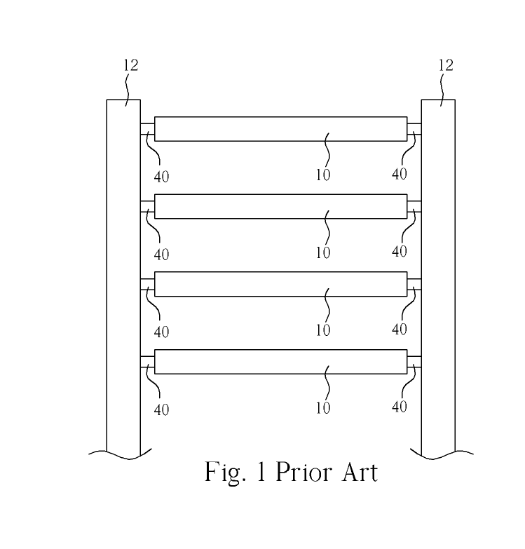

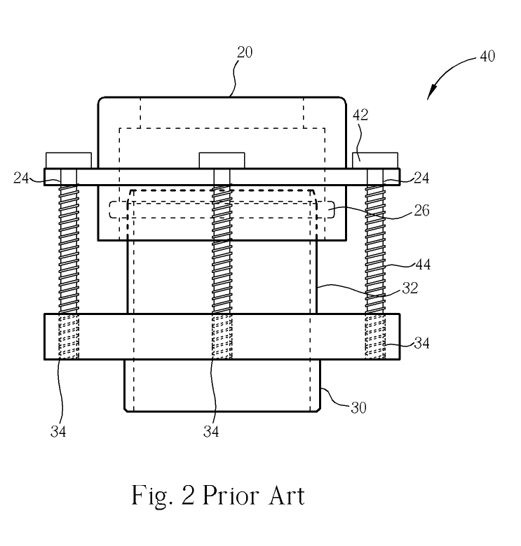

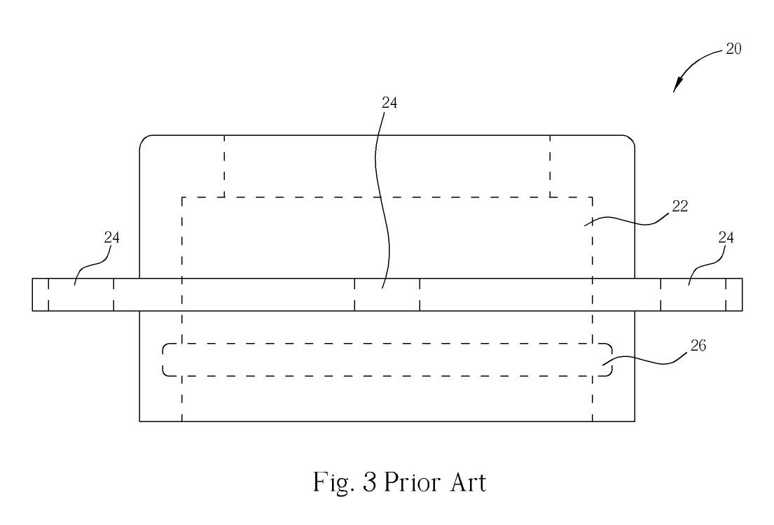

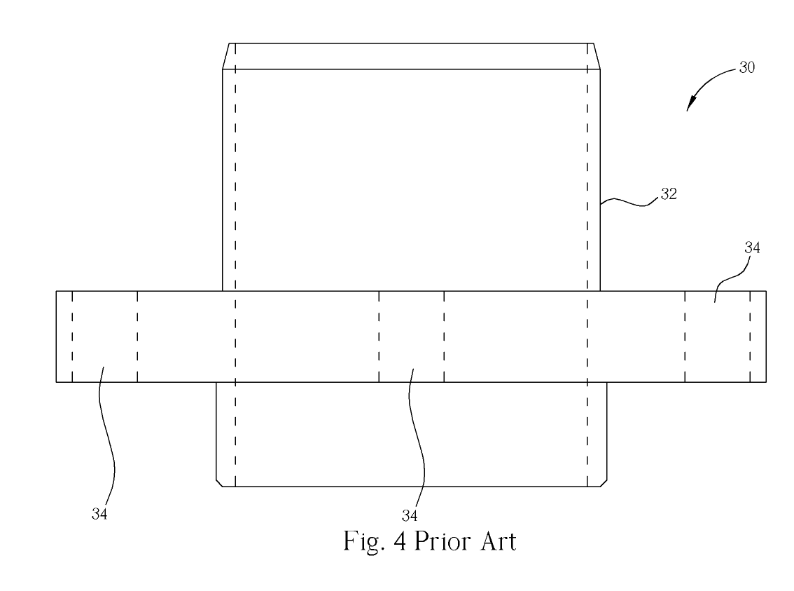

### DETAILED DESCRIPTION

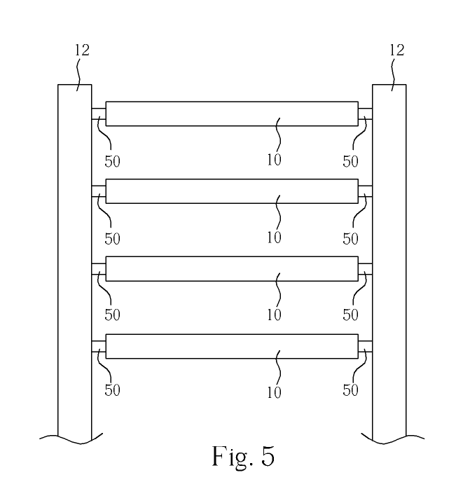

Please refer FIG. 5, which is a diagram of chemical vapor deposition equipment according to the present invention. Each reactor 10 comprises two exhaust ends connected to the exhausted pipe 12 via an adjustable pipe 50 for releasing exhaust gas.

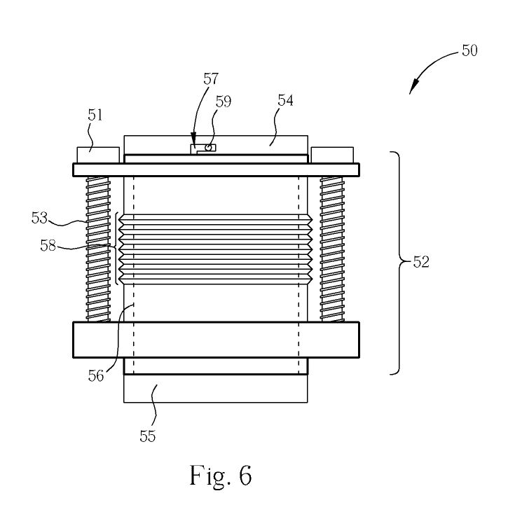

Please refer to FIG. 6, which is a structure of an adjustable pipe 50 according to the present invention. The adjustable pipe 50 comprises a compressible body 52, a bushing 56, and a ring 54. The compressible part of the compressible body 52 is a welded bellows 58, making the entire adjustable pipe 50 compressible.

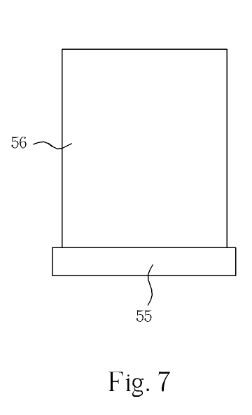

Please refer to FIG. 7, which is a structure of a bushing 56 of the adjustable pipe 50 according to the present invention. A width of an end 55 of the bushing 56 is wider. After the bushing 56 is positioned inside the compressible body 52, the end 55 is outside the compressible body 52 for connecting with the exhaust end of the reactor 10. The bushing 56 can prevent exhaust gas from contacting the welded bellows 58 and remaining inside the welded bellows 58. Since the material of the bushing 56 is aluminum alloy and the exhaust end of the reactor 10 is also made of aluminum alloy, the thermal expansion coefficients are the same. Consequently, when the reactor 10 is heated to high temperatures, the end 55 of the bushing 56 is closely connected to the exhaust end of the reactor 10 to prevent contaminants from leaking during an exhaust gas releasing process.

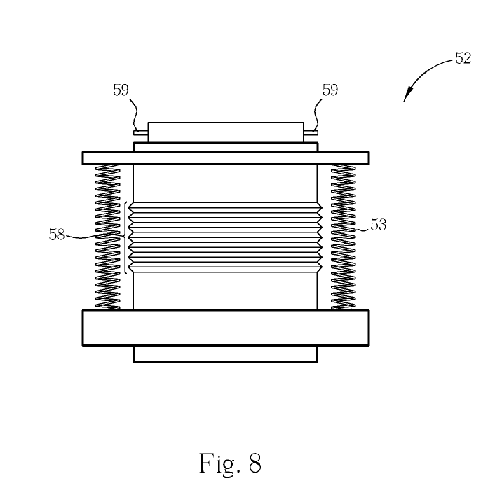

The ring 54 is positioned at an end of the compressible body 52 for connecting with the exhausted pipe 12. Please refer to FIG. 8, which is a structure of the compressible body 52 of the adjustable pipe 50 according to the present invention. There is a rod 59 on the compressible body 52 for fixing the ring 54. A slot 57 of the ring 54 engages the rod 59 of the compressible body 52 to fix the ring 54 on the compressible body 52. Surrounding the compressible body 52, there is a plurality of springs 53. Bolts 51 are respectively positioned through each spring 53. The springs 53 and bolts 51 can assist the ring 54 in connecting with the exhausted pipe 12 closely. When the exhausted pipe 12 presses against the ring 54, the springs 53 can provide a reaction force to the ring 54 such that the ring 54 is tightly connected to the exhausted pipe 12. The material of the ring 54 is Teflon (TM), which has good heat-resistance and high hardness, and can bear the pressure of the exhausted pipe 12 and the reaction force of the springs 53.

The prior art utilizes two aluminum alloy sleeves 20 and 30 to make the expansion pipe 40 somewhat leak proof and a perfluor O-ring for additional leak proofing, but exhaust gas leakage still occurs. In the present invention, the compressible body 52 of the adjustable pipe 50 is monolithically formed so as to prevent exhaust gas from leaking from the compressible body 52. In addition, the entire compressible body 52 is made of stainless steel, and so is the welded bellows 58. Compared to aluminum alloy used in the prior art, stainless steel adopted by the present invention can increase the lifespan of the adjustable pipe 50. The aluminum alloy bushing 56 can prevent exhaust gas from directly contacting the welded bellows 58 so that contaminants do not accumulate inside the bellows. Additionally, the compressible body 52 can be another type of compressible pipe.

Compared to the prior art, the monolithically formed adjustable pipe 50 can solve the problem of exhaust gas leakage. In addition, the present invention can increase the lifespan of the adjustable pipe 50, and improve the seal between the adjustable pipe 50 and the exhausted pipe 12 so as to improve the quality of products manufactured by CVD processes and protect the equipment used in such processes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A chemical vapor deposition equipment comprising:
a reactor having an exhaust end;
an adjustable pipe comprising:
a compressible body having a bellows;
a bushing positioned inside the bellows, an end of the bushing connected to the exhaust end of the reactor; and
a ring positioned at an end of the compressible body for connecting to an exhausted pipe; and
an exhausted pipe connected to the ring of the adjustable pipe.

2. The chemical vapor deposition equipment of claim 1, wherein the bellows is a welded bellows.

3. The chemical vapor deposition equipment of claim 1, wherein the bushing is an aluminum alloy bushing.

4. The chemical vapor deposition equipment of claim 1, wherein the ring is a Teflon ring.

5. The chemical vapor deposition equipment of claim 1, wherein the compressible body is a stainless steel body.

6. The chemical vapor deposition equipment of claim 1, wherein the compressible body further comprises a spring, and the adjustable pipe further comprises a bolt positioned through the spring for providing a reaction force to the ring when the exhausted pipe presses against the ring.

7. The chemical vapor deposition equipment of claim 1, wherein the compressible body further comprises a rod, and the ring further comprises a slot for locking the rod to assemble the ring to the compressible body.

8. An adjustable pipe implemented in a chemical vapor deposition equipment, comprising:
a compressible body having a bellows;
a bushing positioned inside the bellows, an end of the bushing connected to an exhaust end of the reactor; and
a ring positioned at an end of the compressible body for connecting to an exhausted pipe.

9. The adjustable pipe of claim 8, wherein the bellows is a welded bellows.

10. The adjustable pipe of claim 8, wherein the bushing is an aluminum alloy bushing.

11. The adjustable pipe of claim 8, wherein the ring is a Teflon ring.

12. The adjustable pipe of claim 8, wherein the compressible body is a stainless steel body.

13. The adjustable pipe of claim 8, wherein the compressible body further comprises a spring, and the adjustable pipe further comprises a bolt positioned through the spring for providing a reaction force to the ring when the exhausted pipe presses against the ring.

14. The adjustable pipe of claim 8, wherein the compressible body further comprises a rod, and the ring further comprises a slot for locking the rod to assemble the ring to the compressible body.
